(19) United States
(12) Patent Application Publication
(10) Pub. No.: US 2005/0287392 A1
(43) Pub. Date: Dec. 29, 2005

(54) Organic electroluminescent device, method for producing the same, and electronic apparatus

(75) Inventor: Naoyuki Toyoda, Suwa-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/119,783

(22) Filed: May 3, 2005

(30) Foreign Application Priority Data
Jun. 25, 2004 (JP) 2004-188353

(51) Int. Cl. H05B 33/12

(52) U.S. Cl. 428/690; 428/917; 428/447; 428/448; 313/504; 313/506; 427/66

(57) ABSTRACT

An organic electroluminescent device including a hole-injecting or hole-transporting layer; a luminescent layer; and an affinity film for improving an affinity between the hole-injecting or hole-transporting layer and the luminescent layer, the hole-injecting or hole-transporting layer and the luminescent layer being formed by a droplet-discharging process, wherein the affinity film is disposed between the hole-injecting or hole-transporting layer and the luminescent layer.

### BACKGROUND OF THE INVENTION

1. Technical Field

The present invention relates to an organic electroluminescent device, a method for producing the organic electroluminescent device, and an electronic apparatus.

2. Related Art

In recent years, development of electroluminescent elements as light-emitting display devices that replace liquid crystal display devices has been accelerated. With respect to organic electroluminescent elements using organic compounds, the following processes have mainly been developed: a process for forming a film composed of a low-molecular weight compound by vapor deposition, as described in Appl. Phys. Lett. Sep. 21, 1987, 51(12), page 913; and a process for applying a polymer, as described in Appl. Phys. Lett. 71(1), Jul. 7, 1997, page 34-. In particular, inkjet processes using such polymers have been receiving attention in producing color display devices due to the ease of patterning. When a polymer is used, a hole-injecting layer or a hole-transporting layer is often produced between an anode and a luminescent layer. In general, a buffer layer or the hole-transporting layer is frequently composed of a conductive polymer such as a polythiophene derivative or a polyaniline derivative. In low-molecular-weight compounds, the hole-injecting layer or the hole-transporting layer is often composed of a phenylamine derivative.

Japanese Unexamined Patent Application Publication No. 10-153967 discloses a process for forming a pattern of luminescent layers by an inkjet process (droplet-discharging process) with a polymeric material and then forming a layer on the resulting pattern by vapor deposition with a low-molecular compound material to produce a stacked layer.

Applying and patterning the polymeric layers can be performed at the same time by the inkjet process. Furthermore, minimum amounts of materials are required. On the other hand, the other applying processes each have an advantage in that they use a simple apparatus, for example, a spin coater.

However, the above-described related art has the following problems.

When patterning and stacking are performed by the above-described applying process, since the hole-transporting layer is adjacent to the luminescent layer, an already-formed organic film is dissolved in a solvent of an applied liquid. That is, compatibility is a problem. Therefore, when these layers are formed, use of different solvents (for example, an aqueous solvent for the hole-transporting layer and an aromatic solvent for the luminescent layer) is required.

In this case, there is a problem in that it is difficult to uniformly form a film because of low wettability due to low affinity in applying a liquid material for either the luminescent layer or the hole-transporting layer on the other layer that has been formed.

### SUMMARY

An advantage of the invention is that it provides an organic electroluminescent device that can avoid compatibility problem and can thus uniformly produce a film; a method for producing the organic electroluminescent device; and an electronic apparatus including the organic electroluminescent device.

According to an aspect of the invention, an organic electroluminescent device includes a hole-injecting or hole-transporting layer; a luminescent layer; and an affinity film for improving an affinity between the hole-injecting or hole-transporting layer and the luminescent layer, the hole-injecting or hole-transporting layer and the luminescent layer being formed by a droplet-discharging process, wherein the affinity film is disposed between the hole-injecting or hole-transporting layer and the luminescent layer.

According to another aspect of the invention, a method for producing an organic electroluminescent device includes forming a hole-injecting or hole-transporting layer by a droplet-discharging process; forming a luminescent layer by the droplet-discharging process; and forming an affinity film on either the luminescent layer or the hole-injecting or hole-transporting layer to improve an affinity between the hole-injecting or hole-transporting layer and the luminescent layer.

Thus, according to the organic electroluminescent device and the method, even in the case of forming the hole-injecting or hole-transporting layer and the luminescent layer by droplet discharging with a different solvents in order to avoid compatibility problem, when the droplet of a liquid material for either the luminescent layer or the hole-injecting or hole-transporting layer is discharged onto the affinity film on the other layer that has been formed, the droplet of the liquid material can wet and spread on the surface of the affinity film because of an improved affinity of the affinity film to the discharged liquid material. Thus, a uniform layer, which is either the luminescent layer or the hole-injecting or hole-transporting layer, can be formed.

The affinity film may contain a silane compound such as a silane coupling agent or a surfactant.

The affinity film may be suitably formed by chemical vapor deposition or liquid-phase process such as dipping, spin coating or a droplet-discharging process.

The organic electroluminescent device according to the invention may further include a partition for partitioning the hole-injecting or hole-transporting layer and the luminescent layer, the partition having liquid repellency against a material constituting the affinity film. Furthermore, the method for producing the organic electroluminescent device may further include a step of forming a partition for partitioning the hole-injecting or hole-transporting layers and the luminescent layers, the partition having repellency to a material constituting the affinity film.

Thus, according to the organic electroluminescent device and the method, in forming the hole-injecting or hole-transporting layer and the luminescent layer, a droplet is discharged into a portion surrounded by the partitions to produce a pixel, which emits predetermined color light, without color mixing. Furthermore, the invention can prevent formation of the affinity film on the partition in forming the affinity film.

According to another aspect of the invention, an electronic apparatus includes the organic electroluminescent device as a display.

Thus, an electronic apparatus including a display that has excellent image quality and luminous efficiency and has the hole-injecting or hole-transporting layer and the luminescent layer each having a uniform thickness, can be obtained.

### BRIEF DESCRIPTION OF THE DRAWINGS

The invention will be described with reference to the accompanying drawings, wherein like numbers reference like elements, and wherein:

FIG. 1 is a schematic circuit diagram of an organic electroluminescent display according to an embodiment of the invention;

FIG. 2 is a plan view showing a pixel;

FIG. 3 is a schematic cross-sectional view taken along line A-A in FIG. 2;

FIG. 4 is a schematic view showing the bonding state of an intermediate layer;

FIG. 5 is a perspective view showing a droplet-discharging device according to an embodiment;

FIG. 6 is an exploded perspective view showing a droplet-discharging head;

FIG. 7 is an enlarged perspective view showing the droplet-discharging head;

FIGS. 8A to 8C each are schematic cross-sectional view showing production steps according to an embodiment;

FIGS. 9A to 9C each are schematic cross-sectional view showing production steps according to an embodiment;

FIGS. 10A and 10B each are a schematic view showing the spread state of the droplet of a material for a luminescent layer; and

FIGS. 11A to 11C each show an example of an electronic apparatus according to the invention.

### DESCRIPTION OF THE EMBODIMENTS

An organic electroluminescent device, a method for producing the organic electroluminescent device, and an electronic apparatus will be described with reference to the drawings. An exemplary organic electroluminescent display including the inventive organic electroluminescent devices functioning as pixels arranged on a base will be described in the following embodiments. This organic electroluminescent display can be suitably used as a display in, for example, an electronic apparatus.

(Organic Electroluminescent Device)

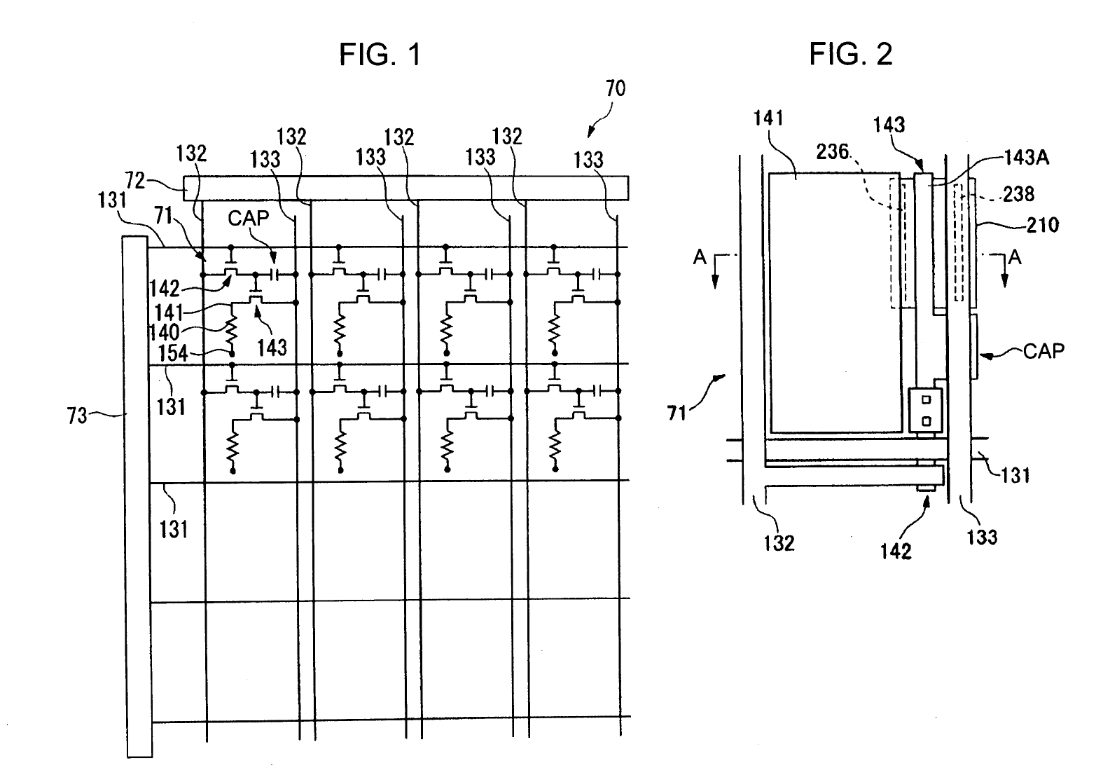

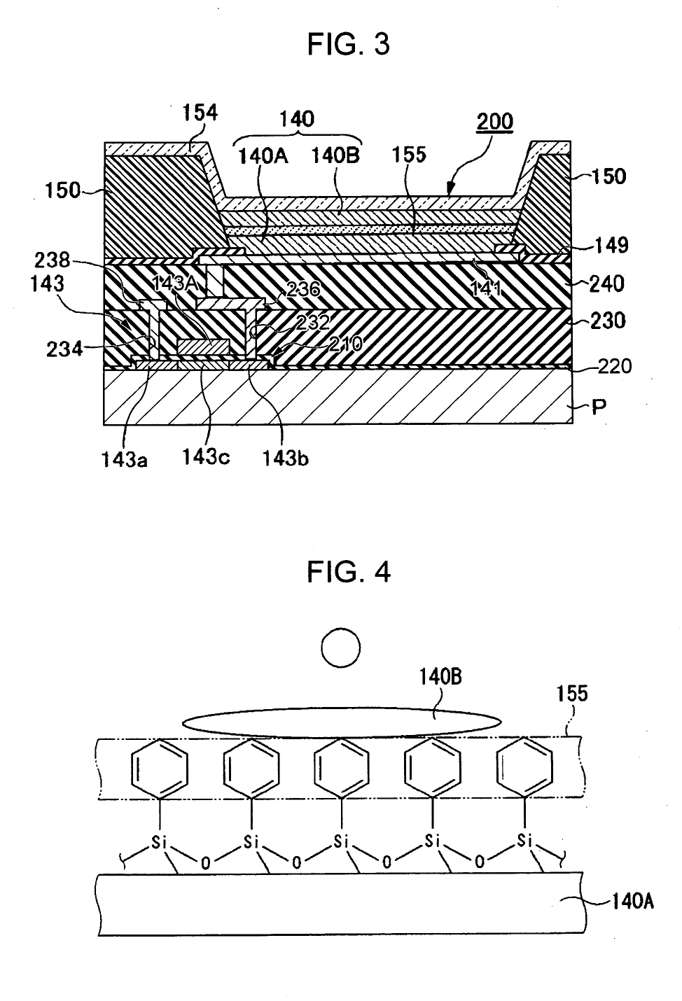

FIG. 1 is a schematic circuit diagram of an organic electroluminescent display according to this embodiment. FIG. 2 is a plan view showing each pixel 71 in the organic electroluminescent display without a reflecting electrode and an organic functioning layer. FIG. 3 is a cross-sectional view taken along line A-A in FIG. 2.

As shown in FIG. 1, an organic electroluminescent display 70 includes a plurality of scanning lines (power lines) 131, a plurality of signal lines (power lines) 132 that are disposed perpendicular to the scanning lines 131, and a plurality of common power source lines 133 that are disposed parallel to the signal lines 132, formed on a transparent substrate. The pixels 71 are provided at the respective intersections of the scanning lines 131 and signal lines 132.

The signal lines 132 are connected to a data-line-driving circuit 72 including a shift register, a level shifter, a video line, an analog switch, and the like. The scanning lines 131 are connected to a scanning-line-driving circuit 73 including a shift register, a level shifter, and the like. Each of the pixels 71 includes a switching thin film transistor (TFT) 142 having a gate electrode to which a scanning signal (power) is supplied through the corresponding scanning line 131, a storage capacitor cap retaining an image signal (power) from the corresponding signal line 132 via the switching TFT 142, a driving TFT 143 having a gate electrode to which the image signal retained in the storage capacitor cap is supplied, a pixel electrode 141 into which a driving current (power) flows from the common power source lines 133 when the pixel electrode is coupled to the corresponding common power source lines 133 via the driving TFT 143, and a luminescent portion 140 disposed between the pixel electrode 141 and a common electrode 154. The pixel electrode 141, the common electrode 154, and the luminescent portion 140 define an organic electroluminescent device (organic electroluminescent element).

According to the organic electroluminescent device, driving a scanning line 131 allows respective switching TFTs 142 to be in an ON mode, and the potential (power) of the signal lines 132 at this time is stored in the storage capacitor cap. An ON or an OFF mode of the driving TFTs 143 is determined based on the state of the storage capacitor cap. Then, a current passes from the common power source lines 133 to the pixel electrodes 141 via channels of the driving TFTs 143 and through the common electrode 154 via the luminescent portions 140. The luminescent portions 140 emit light in accordance with current flowing in the luminescent portion 140.

With reference to a plan view of the pixel 71 shown in FIG. 2, the pixel 71 includes the pixel electrode 141 surrounded by the signal line 132, the common power source line 133, the scanning line 131, and a scanning line for another electrode (not shown). With reference to a cross-sectional view of the pixel 71 shown in FIG. 3, the driving TFT 143 is provided on a substrate (base) P. An organic electroluminescent element 200 is provided on the substrate P with a plurality of insulating films therebetween, the insulating films covering the driving TFT 143. The organic electroluminescent element 200 is provided at a region surrounded by banks (partitions) 150 above the substrate P and includes an organic functional layer 140 between the pixel electrode 141 and the common electrode 154.

The driving TFT 143 mainly includes a source region 143a, a drain region 143b, and a channel region 143c, provided in a semiconductor layer 210; and a gate electrode 143A on a gate-insulating layer 220, the source region 143a being opposite the channel region 143c. A first interlayer insulating film 230 covers the semiconductor layer 210 and the gate-insulating layer 220. A drain electrode 236 and a source electrode 238 are provided in contact holes 232 and 234, respectively, the contact holes being connected to the semiconductor layer 210 through the first interlayer insulating film 230. The drain electrode 236 and the source electrode 238 are conductively connected to the drain region 143b and the source region 143a, respectively. A second interlayer insulating film 240 is provided on the first interlayer insulating film 230. The pixel electrode 141 is partially provided in the contact hole through the second interlayer insulating film 240. The driving TFT 143 is electrically coupled to the pixel electrode 141 (organic electroluminescent element 200) by conductively connecting the pixel electrode 141 with the drain electrode 236. Inorganic banks 149 each partially cover the peripheral portion of the corresponding pixel electrode 141. Organic banks 150, each composed of an organic material, are provided on the respective inorganic banks 149.

The organic functional layer 140 in the organic electroluminescent element 200 includes a hole-transporting sublayer 140A and a luminescent sublayer 140B. An intermediate layer 155 is provided between the hole-transporting sublayer 140A and the luminescent sublayer 140B. The hole-transporting sublayer 140A improves the ability to transport holes to the luminescent sublayer 140B to enhance luminous efficiency. Examples of a material for the hole-transporting sublayer 140A include low-molecular compounds such as benzidine derivatives, styrylamine derivatives, triphenylmethane derivatives, triphenylamine derivatives, arylamine derivatives, and hydrazone derivatives; and polymeric compounds such as polyanilines, polythiophenes, polyvinylcarbazoles, mixtures containing poly (3,4-ethylenedioxythiophene) and polystyrenesulfonic acid (PEDOT/PSS; polyethylendioxythiophene/polystyrene sulfonete (trade name: Baytron P, manufactured by Bayer Aktiengesellschaft)). Among these, α-NPD (α-naphthylphenyldiamine) is often used and is particularly preferable.

A material for the luminescent sublayer 140B mainly constituting the luminescent portion of the organic electroluminescent element 200 may be a known luminescent material that can fluoresce or phosphoresce. In this embodiment, the luminescent sublayer 140B has a liquid phase and is produced by a liquid-phase process such as a droplet-discharging process.

Specific examples of the luminescent sublayer 140B include (poly)fluorene derivatives (PF), (poly)-p-phenylene vinylene derivatives (PPV), polyphenylene derivatives (PP), poly-p-phenylene derivatives (PPP), polyvinylcarbazole (PVK), polythiophene derivatives, and polysilanes such as polymethylphenylsilane (PMPS). These polymeric materials may be doped with polymeric pigments such as perylene pigment, coumalin pigment, and rhodamine pigment, or low molecular weight materials such as rubrene, perylene, 9,10-diphenylanthracene, tetraphenylbutadiene, Nile red, coumalin 6, and quinacridone.

Examples of a compound emitting red light among these organic compounds include a polymeric compound containing a polyvinylenestyrene derivative having an alkyl- or alkoxy-substituted benzene ring and a polymeric compound containing a polyvinylenestyrene derivative having a cyano-substituted vinylene group. An example of an organic compound emitting green light includes a polyvinylenestyrene derivative having an alkyl-, alkoxy-, or aryl derivative-substituted benzene ring. Examples of an organic compound emitting blue light include polyfluorene derivatives such as a copolymer containing dialkylfluorene and anthracene.

Known low-molecular weight materials may be used instead of the polymeric material. If necessary, an electron-injecting layer, such as a laminate composed of lithium fluoride and calcium, may be provided.

The luminescent sublayer 140B is formed by dissolving the material described above into a solvent, applying it onto the intermediate layer 155, and then evaporating the solvent. Examples of the solvent include nonpolar solvents such as toluene, xylene, cyclohexylbenzene, dihydrobenzofuran, trimethylbenzene, and tetramethylbenzene.

The intermediate layer 155 between the hole-transporting sublayer 140A and the luminescent sublayer 140B has a surface-modifying function, i.e., the intermediate layer 155 improves the affinity between the hole-transporting sublayer 140A and the luminescent sublayer 140B. In this embodiment, the intermediate layer 155 modifies the surface properties of the hole-transporting sublayer 140A, thus improving coverage of a liquid material. Therefore, the luminescent sublayer 140B having a uniform thickness and quality is obtained. Effects of the intermediate layer 155 will be described below.

The hole-transporting sublayer 140A is formed by a liquid phase process. When a dispersion containing PEDOT/PSS and a polar solvent is used, the surface of the hole-transporting sublayer 140A obtained is hydrophilic. When the luminescent sublayer 140B is formed on the hole-transporting sublayer 140A by the liquid phase process, use of an aromatic solvent (nonpolar solvent) as the solvent for the luminescent sublayer 140B causes poor wettability due to a low affinity to the surface of the hole-transporting sublayer 140A. As a result, the liquid material for the luminescent sublayer 140B is unevenly provided on the surface of the hole-transporting sublayer 140A, thus reducing uniformity of the thickness and quality of the luminescent sublayer 140B obtained.

On the other hand, in the invention, the intermediate layer 155 modifies the hydrophilic surface of the hole-transporting sublayer 140A to produce a lipophilic surface, thus improving the affinity (wettability) to the liquid material for the luminescent sublayer 140B. Therefore, the uniformity of the thickness and quality of the luminescent sublayer 140B formed can be improved.

The thickness of the intermediate layer 155 is preferably about 1 to 10 molecular layers because an excessive thickness may prevent the recombination of an electron and a hole.

The intermediate layer 155 is preferably composed of a molecule containing a polar group and a nonpolar group, namely, an amphipatic molecule. Orientation of the amphipatic molecules along the thickness results in orientation of the polar groups or the nonpolar groups, thus leading to modification of the surface.

That is, when the polar groups in the amphipatic molecules in the intermediate layer 155 are connected to the surface of the hole-transporting sublayer 140A, the nonpolar groups are arranged at the surface of the intermediate layer 155, thus modifying the surface of the hole-transporting sublayer 140A. As a result, the wettability of the liquid material is enhanced.

Silane coupling agents (silane compounds) and surfactants can be suitably used as a material for the intermediate layer 155. When using the silane compound, silanol groups (SiOHs) formed as a result of hydrolysis of some of the hydrolyzable groups in the silane compound are adsorbed on the surface, on which the intermediate layer 155 is formed, of the hole-transporting sublayer 140A. Alternatively, surface atoms Ms at the surface of the hole-transporting sublayer 140A and the silane compound are allowed to react directly or indirectly to be bonded together. For example, the silanol groups (SiOHs) formed as a result of hydrolysis of some of the hydrolyzable groups in the silane compound and the surface atoms Ms (or MOH) are allowed to react to form Si—O-M bonds (see FIG. 4).

The intermediate layer 155 is composed of (A) at least one type of silane compound (component A) represented by general formula (I):
R¹SiX¹ₘX²₍₃₋ₘ₎ (I)
(where R¹ represents an organic group; X¹ and X² each represent —OR², —R², or —Cl; R² represents an alkyl group having 1 to 4 carbon atoms; and m is integer of 1 to 3), or (B) an amphipatic compound represented by general formula (II):
R¹Y¹ (II)
(where Y¹ represents a polar group such as —OH, —(CH₂CH₂O)ₙH, —COOH, —COOK, —COONa, —CONH₂, —SO₃H, —SO₃Na, —OSO₃H, —OSO₃Na, —PO₃H₂, —PO₃Na₂, —PO₃K₂, —NO₂, —NH₂, —NH₃Cl (ammonium salt), —NH₃Br (ammonium salt), ≡NHCl (pyridinium salt), ≡NHBr (pyridinium salt).

The silane compound is substituted with an organic group and an alkoxy group, an alkyl group, or chlorine. R¹ enhances the affinity and adherability to the material of the luminescent layer. The enhanced affinity and adherability to the hole-transporting layer result from an affinity such as an affinity to the solvent, Van der Waals attraction, or electrostatic attraction; or formation of a bond such as a covalent bond, an ionic bond, a coordinate bond, or a hydrogen bond. Examples of the organic group R¹ include phenyl, benzyl, phenethyl, hydroxyphenyl, chlorophenyl, aminophenyl, naphthyl, anthryl, pyrenyl, thienyl, pyroryl, cyclohexyl, cyclohexenyl, cyclopentyl, cyclopentenyl, pyridinyl, methyl, ethyl, n-propyl, isopropyl, n-butyl, isobutyl, sec-butyl, tert-butyl, octadecyl, n-octyl, chloromethyl, methoxyethyl, hydroxyethyl, aminoethyl, cyano, mercaptopropyl, vinyl, allyl, acryloxyethyl, methacryloxyethyl, glycidoxypropyl, and acetoxy. X¹ represents an alkoxyl group, chlorine, or a functional group for forming, for example, a Si—O—Si bond. X¹ is hydrolyzed and eliminated in the form of an alcohol or an acid. Examples of the alkoxyl group include methoxy, ethoxy, n-propoxy, isopropoxy, n-butoxy, isobutoxy, sec-butoxy, and tert-butoxy. The number of carbon atoms in R² is preferably in the range 1 to 4 so that an alcohol formed has a relatively low molecular weight and thus is easily eliminated to prevent a reduction in density of a film formed.

Examples of the silane compound represented by general formula (I) include dimethyldimethoxysilane, diethyldiethoxysilane, 1-propenylmethyldichlorosilane, propyldimethylchlorosilane, propylmethyldichlorosilane, propyltrichlorosilane, propyltriethoxysilane, propyltrimethoxysilane, styrylethyltrimethoxysilane, tetradecyltrichlorosilane, 3-thiocyanatopropyltriethoxysilane, p-tolyldimethylchlorosilane, p-tolylmethyldichlorosilane, p-tolyltrichlorosilane, p-tolyltrimethoxysilane, p-tolyltriethoxysilane, di-n-propyldi-n-propoxysilane, diisopropyldiisopropoxysilane, di-n-butyldi-n-butyloxysilane, di-sec-butyldi-sec-butyloxybutyloxysilane, di-tert-butyldi-tert-butyloxysilane, octadecyltrichlorosilane, octadecylmethyldiethoxysilane, octadecyltriethoxysilane, octadecyltrimethoxysilane, octadecyldimethylchlorosilane, octadecylmethyldichlorosilane, octadecylmethoxydichlorosilane, 7-octenyldimethylchlorosilane, 7-octenyltrichlorosilane, 7-octenyltrimethoxysilane, octylmethyldichlorosilane, octyldimethylchlorosilane, octyltrichlorosilane, 10-undecenyldimethylchlorosilane, undecyltrichlorosilane, vinyldimethylchlorosilane, methyloctadecyldimethoxysilane, methyldodecyldiethoxysilane, methyloctadecyldimethoxysilane, methyloctadecyldiethoxysilane, n-octylmethyldimethoxysilane, n-octylmethyldiethoxysilane, triacontyldimethylchlorosilane, triacontyltrichlorosilane, methyltrimethoxysilane, methyltriethoxysilane, methyltri-n-propoxysilane, methylisopropoxysilane, methyl-n-butyloxysilane, methyltri-sec-butyloxysilane, methyltri-tert-butyloxysilane, ethyltrimethoxysilane, ethyltriethoxysilane, ethyltri-n-propoxysilane, ethylisopropoxysilane, ethyl-n-butyloxysilane, ethyltri-sec-butyloxysilane, ethyltri-t-butyloxysilane, n-propyltrimethoxysilane, isobutyltrimethoxysilane, n-hexyltrimethoxysilane, hexadecyltrimethoxysilane, n-octyltrimethoxysilane, n-dodecyltrimethoxysilane, n-octadecyltrimethoxysilane, n-propyltriethoxysilane, isobutyltriethoxysilane, n-hexyltriethoxysilane, hexadecyltriethoxysilane, n-octyltriethoxysilane, n-dodecyltrimethoxysilane, n-octadecyltriethoxysilane, 2-[2-(trichlorosilyl)ethyl]pyridine, 4-[2-(trichlorosilyl)ethyl]pyridine, diphenyldimethoxysilane, diphenyldiethoxysilane, 1,3-(trichlorosilylmethyl)heptacosane, dibenzyldimethoxysilane, dibenzyldiethoxysilane, phenyltrimethoxysilane, phenylmethyldimethoxysilane, phenyldimethylmethoxysilane, phenyldimethoxysilane, phenyldiethoxysilane, phenylmethyldiethoxysilane, phenyldimethylethoxysilane, benzyltriethoxysilane, benzyltrimethoxysilane, benzylmethyldimethoxysilane, benzyldimethylmethoxysilane, benzyldimethoxysilane, benzyldiethoxysilane, benzylmethyldiethoxysilane, benzyldimethylethoxysilane, benzyltriethoxysilane, dibenzyldimethoxysilane, dibenzyldiethoxysilane, 3-acetoxypropyltrimethoxysilane, 3-acryloxypropyltrimethoxysilane, allyltrimethoxysilane, allyltriethoxysilane, 4-aminobutyltriethoxysilane, (aminoethylaminomethyl)phenethyltrimethoxysilane, N-(2-aminoethyl)-3-aminopropylmethyldimethoxysilane, N-(2-aminoethyl)-3-aminopropyltrimethoxysilane, 6-(aminohexylaminopropyl)trimethoxysilane, p-aminophenyltrimethoxysilane, p-aminophenylethoxysilane, m-aminophenyltrimethoxysilane, m-aminophenylethoxysilane, 3-aminopropyltrimethoxysilane, 3-aminopropyltriethoxysilane, ω-aminoundecyltrimethoxysilane, amyltriethoxysilane, benzooxasilepin dimethyl ester, 5-(bicycloheptenyl)triethoxysilane, bis(2-hydroxyethyl)-3-aminopropyltriethoxysilane, 8-bromooctyltrimethoxysilane, bromophenyltrimethoxysilane, 3-bromopropyltrimethoxysilane, n-butyltrimethoxysilane, 2-chloromethyltriethoxysilane, chloromethylmethyldiethoxysilane, chloromethylmethyldiisopropoxysilane, p-(chloromethyl)phenyltrimethoxysilane, chloromethyltriethoxysilane, chlorophenyltriethoxysilane, 3-chloropropylmethyldimethoxysilane, 3-chloropropyltriethoxysilane, 3-chloropropyltrimethoxysilane, 2-(4-chlorosulfonylphenyl)ethyltrimethoxysilane, 2-cyanoethyltriethoxysilane, 2-cyanoethyltrimethoxysilane,cyanomethylphenethyltriethoxysilane, 3-cyanopropyltriethoxysilane, 2-(3-cyclohexenyl)ethyltrimethoxysilane, 2-(3-cyclohexenyl)ethyltriethoxysilane, 3-cyclohexenyltrichlorosilane, 2-(3-cyclohexenyl)ethyltrichlorosilane, 2-(3-cyclohexenyl)ethyldimethylchlorosilane, 2-(3-cyclohexenyl)ethylmethyldichlorosilane, cyclohexyldimethylchlorosilane, cyclohexylethyldimethoxysilane, cyclohexylmethyldichlorosilane, cyclohexylmethyldimethoxysilane, (cyclohexylmethyl)trichlorosilane, cyclohexyltrichlorosilane, cyclohexyltrimethoxysilane, cyclooctyltrichlorosilane, (4-cyclooctenyl)trichlorosilane, cyclopentyltrichlorosilane, cyclopentyltrimethoxysilane, 1,1-diethoxy-1-silacyclopente-3-ne, 3-(2,4-dinitrophenylamino)propyltriethoxysilane, (dimethylchlorosilyl)methyl-7,7-dimethylnorpinane, (cyclohexylaminomethyl)methyldiethoxysilane, (3-cyclopentadienylpropyl)triethoxysilane, N,N-diethyl-3-aminopropyl)trimethoxysilane, 2-(3,4-epoxycyclohexyl)ethyltrimethoxysilane, 2-(3,4-epoxycyclohexyl)ethyltriethoxysilane, (furfuryloxymethyl)triethoxysilane, 2-hydroxy-4-(3-triethoxypropoxy)diphenylketone, 3-(p-methoxyphenyl)propylmethyldichlorosilane, 3-(p-methoxyphenyl)propyltrichlorosilane, p-(methylphenethyl)methyldichlorosilane, p-(methylphenethyl)trichlorosilane, p-(methylphenethyl)dimethylchlorosilane, 3-morpholinopropyltrimethoxysilane, (3-glycidoxypropyl)methyldiethoxysilane, 3-glycidoxypropyltrimethoxysilane, 1,2,3,4,7,7,-hexachloro-6-methyldiethoxysilyl-2-norbornene, 1,2,3,4,7,7-hexachloro-6-triethoxysilyl-2-norbornene, 3-iodopropyltrimethoxysilane, 3-isocyanatopropyltriethoxysilane, (mercaptomethyl)methyldiethoxysilane, 3-mercaptopropylmethyldimethoxysilane, 3-mercaptopropyldimethoxysilane, 3-mercaptopropyltriethoxysilane, 3-methacryloxypropylmethyldiethoxysilane, 3-methacryloxypropyltrimethoxysilane, methyl[2-(3-trimethoxysilylpropylamino)ethylamino]-3-propionate, 7-octenyltrimethoxysilane, (R)-N-α-phenethyl-N′-triethoxysilylpropylurea, (S)-N-α-phenethyl-N′-triethoxysilylpropylurea, phenethyltrimethoxysilane, phenethylmethyldimethoxysilane, phenethyldimethylmethoxysilane, phenethyldimethoxysilane, phenethyldiethoxysilane, phenethylmethyldiethoxysilane, phenethyldimethylethoxysilane, phenethyltriethoxysilane, (3-phenylpropyl)dimethylchlorosilane, (3-phenylpropyl)methyldichlorosilane, N-phenylaminopropyltrimethoxysilane, N-(triethoxysilylpropyl) dansylamide, N-(3-triethoxysilylpropyl)-4,5-dihydroimidazole, 2-(triethoxysilylethyl)-5-(chloroacetoxy)bicycloheptane, (S)-N-triethoxysilylpropyl-O-menthocarbamate, 3-(triethoxysilylpropyl)-p-nitrobenzamide, 3-(triethoxysilyl)propylsuccinic anhydride, N-[5-(trimethoxysilyl)-2-aza-1-oxo-pentyl]caprolactam, 2-(trimethoxysilylethyl)pyridine, N-(trimethoxysilylethyl)benzyl-N,N,N-trimethylammonium chloride, phenylvinyldiethoxysilane, 3-thiocyanatopropyltriethoxysilane, (tridecafluoro-1,1,2,2-tetrahydrooctyl)triethoxysilane, N-[3-(triethoxysilyl)propyl]phthalamic acid, (3,3,3-trifluoropropyl)methyldimethoxysilane, (3,3,3-trifluoropropyl)trimethoxysilane, 1-trimethoxysilyl-2-(chloromethyl)phenylethane, 2-(trimethoxysilyl)ethylphenylsulfonylazide, β-trimethoxysilylethyl-2-pyridine, trimethoxysilylpropyldiethylenetriamine, N-(3-trimethoxysilylpropyl)pyrrole, N-trimethoxysilylpropyl-N,N,N-tributylammonium bromide, N-trimethoxysilylpropyl-N,N,N-tributylammonium chloride, N-trimethoxysilylpropyl-N,N,N-trimethylammonium chloride, vinylmethyldiethoxysilane, vinyltriethoxysilane, vinyltrimethoxysilane, vinylmethyldimethoxysilane, vinyldimethylmethoxysilane, vinyldimethylethoxysilane, vinylmethyldichlorosilane, vinylphenyldichlorosilane, vinylphenyldiethoxysilane, vinylphenyldimethylsilane, vinylphenylmethylchlorosilane, vinyltriphenoxysilane, vinyltri-tert-butoxysilane, adamantylethyltrichlorosilane, allylphenyltrichlorosilane, (aminoethylaminomethyl)phenethyltrimethoxysilane, 3-aminophenoxydimethylvinylsilane, phenyltrichlorosilane, phenyldimethylchlorosilane, phenylmethyldichlorosilane, benzyltrichlorosilane, benzyldimethylchlorosilane, benzylmethyldichlorosilane, phenethyldiisopropylchlorosilane, phenethyltrichlorosilane, phenethyldimethylchlorosilane, phenethylmethyldichlorosilane, 5-(bicycloheptenyl)trichlorosilane, 5-(bicycloheptenyl)triethoxysilane, 2-(bicycloheptyl)dimethylchlorosilane, 2-(bicycloheptyl)trichlorosilane, 1,4-bis(trimethoxysilylethyl)benzene, bromophenyltrichlorosilane, 3-phenoxypropyldimethylchlorosilane, 3-phenoxypropyltrichlorosilane, tert-butylphenylchlorosilane, tert-butylphenylmethoxysilane, tert-butylphenyldichlorosilane, p-(tert-butyl)phenethyldimethylchlorosilane, p-(tert-butyl)phenethyltrichlorosilane, 1,3-(chlorodimethylsilylmethyl)heptacosane, ((chloromethyl)phenylethyl)dimethylchlorosilane, ((chloromethyl)phenylethyl)methyldichlorosilane, ((chloromethyl)phenylethyl)trichlorosilane, ((chloromethyl)phenylethyl)trimethoxysilane, chlorophenyltrichlorosilane, 2-cyanoethyltrichlorosilane, 2-cyanoethylmethyldichlorosilane, 3-cyanopropylmethyldiethoxysilane, 3-cyanopropylmethyldichlorosilane, 3-cyanopropylmethyldichlorosilane, 3-cyanopropyldimethylethoxysilane, 3-cyanopropylmethyldichlorosilane, 3-cyanopropyltrichlorosilane.

The amphipatic compound represented by general formula (II) is a compound in which an organic group R¹ is bound to a hydrophilic functional group. Y¹ represents a hydrophilic polar group and is a functional group for adsorbing on a hydrophilic surface. Lipophilic groups R¹s of a surfactant are arranged opposite the hydrophilic surface to form a lipophilic surface on the hydrophilic surface. R¹ enhances the affinity and adherability to the material of the luminescent layer. The enhanced affinity and adherability to the hole-transporting layer 140 result from an affinity such as an affinity to the solvent, Van der Waals attraction, or electrostatic attraction; or formation of a bond such as a covalent bond, an ionic bond, a coordinate bond, or a hydrogen bond. Examples of the organic group R¹ include phenyl, benzyl, phenethyl, hydroxyphenyl, chlorophenyl, aminophenyl, naphthyl, anthryl, pyrenyl, thienyl, pyroryl, cyclohexyl, cyclohexenyl, cyclopentyl, cyclopentenyl, pyridinyl, methyl, ethyl, n-propyl, isopropyl, n-butyl, isobutyl, sec-butyl, tert-butyl, octadecyl, n-octyl, chloromethyl, methoxyethyl, hydroxyethyl, aminoethyl, cyano, mercaptopropyl, vinyl, allyl, acryloxyethyl, methcryloxyethyl, glycidoxypropyl, and acetoxy.

Examples of the amphiphilic compound represented by general formula (II) include n-decyltrimethylammonium xhloride, n-decyltrimethylammonium bromide, n-dodecyltrimethylammonium chloride, n-dodecyltrimethylammonium bromide, n-hexadecyltrimethylammonium chloride, n-hexadecyltrimethylammonium bromide, n-octadecyltrimethylammonium chloride, n-octadecyltrimethylammonium bromide, di-n-dodecyldimethylammonium chloride, di-n-dodecyldimethylammonium bromide, n-decylpyridinium chloride, n-decylpyridinium bromide, n-dodecylpyridinium chloride, n-dodecylpyridinium bromide, n-dodecylpyridinium iodide, n-tetradecylpyridinium chloride, n-tetradecylpyridinium bromide, n-hexadecylpyridinium chloride, n-hexadecylpyridinium bromide, n-hexadecylpyridinium iodide, n-octadecylpyridinium chloride, n-octadecylpyridinium bromide, n-dodecylpicolinium chloride, n-dodecylpicolinium bromide, n-octadecylpicolinium chloride, n-octadecylpicolinium bromide, n- octadecylpicolinium iodide, N,N′-dimethyl-4,4′-bipyridinium dichloride, N,N′-dimethyl-4,4′-bipyridinium dibromide, N,N′-dimethyl-4,4′-bipyridinium bis(methyl sulfate), N,N′-dimethyl-4,4′-bipyridinium bis(p-toluene sulfonate), N,N′-di(n-propyl)-4,4′-bipyridinium dichloride, N,N′-di(n-propyl)-4,4′-bipyridinium dibromide, N,N′-di(n-propyl)-4,4′-bipyridinium bis(p-toluene sulfonate), N,N′-dibenzyl-4,4′-bipyridinium dichloride, N,N′-dibenzyl-4,4′-bipyridinium dibromide, N,N′-dibenzyl-4,4′-bipyridiniumdi iodide, N,N′-dibenzyl-4,4′-bipyridinium bis (p-toluene sulfonate), N,N′-diphenyl-4,4′-bipyridinium dichloride, N,N′-diphenyl-4,4′-bipyridinium dibromide, N,N′-bis(3-sulfonatopropyl)-4,4′-bipyridinium, 1,3-bis[N-(N′-methyl-4,4′-bipyridyl)]propane tetrachloride, 1,3-bis[N-(N′-methyl-4,4′-bipyridyl)]propane tetrabromide, 1,3-bis[N-(N′-benzyl-4,4′-bipyridyl)]propane tetrachloride, 1,3-bis[N-(N′-benzyl-4,4′-bipyridyl)]propane tetrabromide, 1,4-bis[N-(N′-methyl-4,4′-bipyridyl)]butane tetrachloride, 1,4-bis[N-(N′-methyl-4,4′-bipyridyl)]butane tetrabromide, 1,4-bis [N-(N′-benzyl-4,4′-bipyridyl)]butane tetrachloride, 1,4-bis[N-A(N′-benzyl-4,4′-bipyridyl)]butane tetrabromide, α,α′-bis[N-(N′-methyl-4,4′-bipyridyl)]-o-xylene tetrachloride, α,α′-bis [N-(N′-methyl-4,4′-bipyridyl)]-o-xylene tetrabromide, α,α′-bis [N-(N′-benzyl-4,4′-bipyridyl)]-o-xylene tetrachloride, α,α′-bis[N-(N′-benzyl-4,4′-bipyridyl)]-o-xylene tetrabromide, α,α′-bis[N-(N′-methyl-4,4′-bipyridyl)]-m-xylene tetrachloride, α,α′-bis[N-(N′-methyl-4,4′-bipyridyl)]-m-xylene tetrabromide, α,α′-bis [N-(N′-benzyl-4,4′-bipyridyl)]-m-xylene tetrachloride, α,α′-bis[N-(N′-benzyl-4,4′-bipyridyl)]-m-xylene tetrabromide, α,α′-bis[N-(N′-methyl-4,4′-bipyridyl)]-p-xylene tetrachloride, α,α′-bis [N-(N′-methyl-4,41′-bipyridyl)]-p-xylene tetrabromide, α,α′-bis[N-(N′-benzyl-4,4′-bipyridyl)]-p-xylene tetrachloride, α,α′-bis[N-(N′-benzyl-4,4′-bipyridyl)]-p-xylene tetrabromide, N-n-dodecyl-N′-methyl-4,4′-bipyridinium dichloride, N-n-dodecyl-N′-methyl-4,4′-bipyridinium bromide iodide, N-n-dodecyl-N′-methyl-4,4′-bipyridinium bromide methyl sulfate, N-n-dodecyl-N′-benzyl-4,4′-bipyridinium dichloride, N-n-dodecyl-N′-benzyl-4,4′-bipyridinium dibromide, N-n-dodecyl-N′-benzyl-4,4′-bipyridinium chloride bromide, N-n-hexadecyl-N′-methyl-4,4′-bipyridinium dichloride, N-n-hexadecyl-N′-methyl-4,4′-bipyridinium bromide iodide, N-n-hexadecyl-N′-methyl-4,4′-bipyridinium bromide methyl sulfate, N-n-hexadecyl-N′-benzyl-4,4′-bipyridinium dichloride, N-n-hexadecyl-N′-benzyl-4,4′-bipyridinium dibromide, N-n-octadecyl-N′-methyl-4,4′-bipyridinium dichloride, N-n-octadecyl-N′-methyl-4,4′-bipyridinium bromide iodide, N-n-octadecyl-N′-methyl-4,4′-bipyridinium bromide methyl sulfate, N-n-octadecyl-N′-benzyl-4,4′-bipyridinium dibromide, N,N′-di-n-dodecyl-4,4′-bipyridinium dichloride, N,N′-di-n-dodecyl-4,4′-bipyridinium dibromide, N,N′-di-n-hexadecyl-4,4′-bipyridinium dichloride, N,N′-di-n-hexadecyl-4,4′-bipyridinium dibromide, 1,3-bis[N-(N′-n-dodecyl-4,4′-bipyridyl)]propane tetrachloride, 1,3-bis[N-(N′-n-dodecyl-4,4′-bipyridyl)]propane tetrabromide, 1,4-bis[N-(N′-n-dodecyl-4,4′-bipyridyl)]butane tetrabromide, 1,6-bis[N-(N′-n-dodecyl-4,4′-bipyridyl)]hexane tetrabromide, 1,3-bis[N-(N′-n-hexadecyl-4,4′-bipyridyl)]propane tetrabromide, 1,4-bis[N-(N′-n-hexadecyl-4,4′-bipyridyl)]butane tetrabromide, 1,6-bis[N-(N′-n-hexadecyl-4,4′-bipyridyl)]hexane tetrabromide, α,α′-bis[N-(N′-n-dodecyl-4,4′-bipyridyl)]-o-xylene tetrachloride, α,α′-bis[N-(N′-n-dodecyl-4,4′-bipyridyl)]-o-xylene tetrabromide, α,α′-bis[N-(N′-n-dodecyl-4,4′-bipyridyl)]-m-xylene tetrachloride, α,α′-bis[N-(N′-n-dodecyl-4,4′-bipyridyl)]-m-xylene tetrabromide, α,α′-bis[N-(N′-n-dodecyl-4,4′-bipyridyl)]-p-xylene tetrachloride, α,α′-bis[N-(N′-n-dodecyl-4,4′-bipyridyl)]-p-xylene tetrabromide, α,α′-bis[N-(N′-n-hexadecyl-4,4′-bipyridyl)]-o-xylene tetrachloride, α,α′-bis[N-(N′-n-hexadecyl-4,4′-bipyridyl)]-o-xylene tetrabromide, α,α′-bis[N-(N′-n-hexadecyl-4,4′-bipyridyl)]-m-xylene tetrachloride, α,α′-bis[N-(N′-n-hexadecyl-4,4′-bipyridyl)]-m-xylene tetrabromide, α,α′-bis[N-(N′-n-hexadecyl-4,4′-bipyridyl)]-p-xylene tetrachloride, α,α′-bis[N-(N′-n-hexadecyl-4,4′-bipyridyl)]-p-xylene tetrabromide, cyclohexyl acrylate, cyclohexyl methacrylate, cyclohexylacrylamide, cyclohexylmethacrylamide, N-cyclohexyl-N-methylacrylamide, N-cyclohexyl-N-methylmethacrylamide, cyclohexylmethyl acrylate, cyclohexylmethyl methacrylate, cyclohexylmethylacrylamide, cyclohexylmethyl methacrylamide, N-cyclohexylmethyl-N-methylacrylamide, N-cyclohexylmethyl-N-methylmethacrylamide, phenyl acrylate, phenyl methacrylate, phenylacrylamide, phenylmethacrylamide, N-methyl-N-phenylacrylamide, N-methyl-N-phenylmethacrylamide, benzyl acrylate, benzyl methacrylate, benzylacrylamide, benzylmethacrylate, N-benzyl-N-methylacrylamide, N-benzyl-N-methylmethacrylamide, 1-norbornyl acrylate, 1-norbornyl methacrylate, 1-norbornylacrylamide, 1-norbornylmethacrylamide, N-methyl-N-(1-norbornyl)acrylamide, N-methyl-N-(1-norbornyl)methacrylamide, cyclooctyl acrylate, cyclooctyl methacrylate, cyclooctylacrylamide, cyclooctylmethacrylamide, N-cyclooctyl-N-methylacrylamide, N-cyclooctyl-N-methylmethacrylamide, adamantyl acrylate, adamantyl methacrylate, adamantylacrylamide, adamantylmethacrylamide, N-adamantyl-N-methylacrylamide, N-adamantyl-N-methylmethacrylamide, 1-naphthyl acrylate, 1-naphthyl methacrylate, 1-naphthylacrylamide, 1-naphthylmethacrylamide, N-methyl-N-(1-naphthyl)acrylamide, N-methyl-N-(1-naphthyl)methacrylamide, 2-naphthyl acrylate, 2-naphthyl methacrylate, 2-naphthylacrylamide, 2-naphthylmethacrylamide, N-methyl-N-(2-naphthyl)acrylamide, N-methyl-N-(2-naphthyl)methacrylamide, n-dodecyl acrylate, n-dodecyl methacrylate, n-dodecylacrylamide, n-dodecylmethacrylamide, N-n-dodecyl-N-methylacrylamide, N-n-dodecyl-N-methylmethacrylamide, cyclododecyl acrylate, cyclododecyl methacrylate, cyclododecylacrylamide, cyclododecylmethacrylamide, N-cyclododecyl-N-methylacrylamide, N-cyclododecyl-N-methylmethacrylamide, n-hexadecyl acrylate, n-hexadecyl methacrylate, n-hexadecylacrylamide, n-hexadecylmethacrylamide, N-n-hexadecyl-N-methylacrylamide, N-n-hexadecyl-N-methylmethacrylamide, n-octadecyl acrylate, n-octadecyl methacrylate, n-octadecylacrylamide, n-octadecylmethacrylamide, N-n-octadecyl-N-methylacrylamide, N-n-octadecyl-N-methylmethacrylamide, di-n-octylacrylamide, di-n-octylmethacrylamide, di-n-decylacrylamide, di-n-decylmethacrylamide, di-n-dodecylacrylamide, di-n-dodecylmethacrylamide, 9-anthracenemethyl acrylate, 9-anthracenemethyl methacrylate, 9-anthracenemethylacrylamide, 9-anthracenemethylmethacrylamide, 9-phenanthrenemethyl acrylate, 9-phenanthrenemethyl methacrylate, 9-phenanthrenemethylacrylamide, 9-phenanthrenemethylmethacrylamide, N-methyl-N-(9-phenanthrenemethyl)acrylamide, N-methyl-N-(9-phenanthrenemethyl)methacrylamide, 1-pyrenemethyl acrylate, 1-pyrenemethyl methacrylate, 1-pyrenemethylacrylamide, 1-pyrenemethylmethacrylamide, N-methyl-N-(1-pyrenemethyl)acrylamide, N-methyl-N-(1-pyrenemethyl)methacrylamide, and 4-acryloyloxymethylphthalocyanine.

The intermediate layer 155 composed of the above-described material is preferably formed by a vapor-phase process such as chemical vapor deposition; or a liquid-phase process such as droplet-discharging, spin coating, and dipping.

In the case of a top-emission organic electroluminescent display, since light emerges from the side of the organic electroluminescent element 200, the substrate P may use an opaque substrate in addition to a transparent substrate such as glass substrate. Examples of materials for the opaque substrate include ceramics such as alumina, sheets of metal, such as stainless steel, which are subjected to insulation treatment such as surface oxidization, thermosetting or thermoplastic resins, and films of thermosetting or thermoplastic resins. For the top-emission electroluminescent display, the pixel electrode 141 need not to be formed with a transparent conductive material such as indium-tin oxide (ITO); it may be formed with an appropriate conductive material such as a metal.

The common electrode 154 provided above the substrate P covers the top of the luminescent sublayer 140B and the tops and sides of the banks 150. For the top-emission electroluminescent display, a material for the common electrode 154 is a transparent conductive material. ITO is suitably used as the transparent conductive material, but other transparent conductive materials may be used.

A cathode-protecting layer may be provided on the common electrode 154. The cathode-protecting layer retards corrosion of the common electrode 154 in the production process. The cathode-protecting layer may be composed of an inorganic material, for example, a silicon compound such as silicon oxide, silicon nitride, or silicon oxynitride. Covering the common electrode 154 with the cathode-protecting layer composed of such an inorganic material results in prevention of the entry of, for example, oxygen into the cathode composed of an inorganic oxide. (Method for producing organic electroluminescent device)

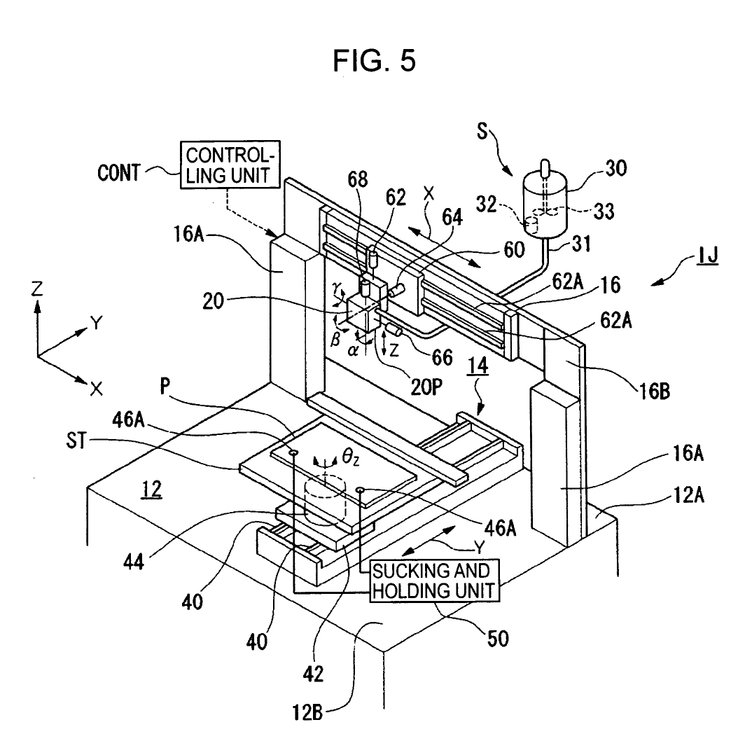

An embodiment of a method for producing an organic electroluminescent device according to the invention will be described with reference to FIGS. 5 to 7.

<Droplet-Discharging Device>

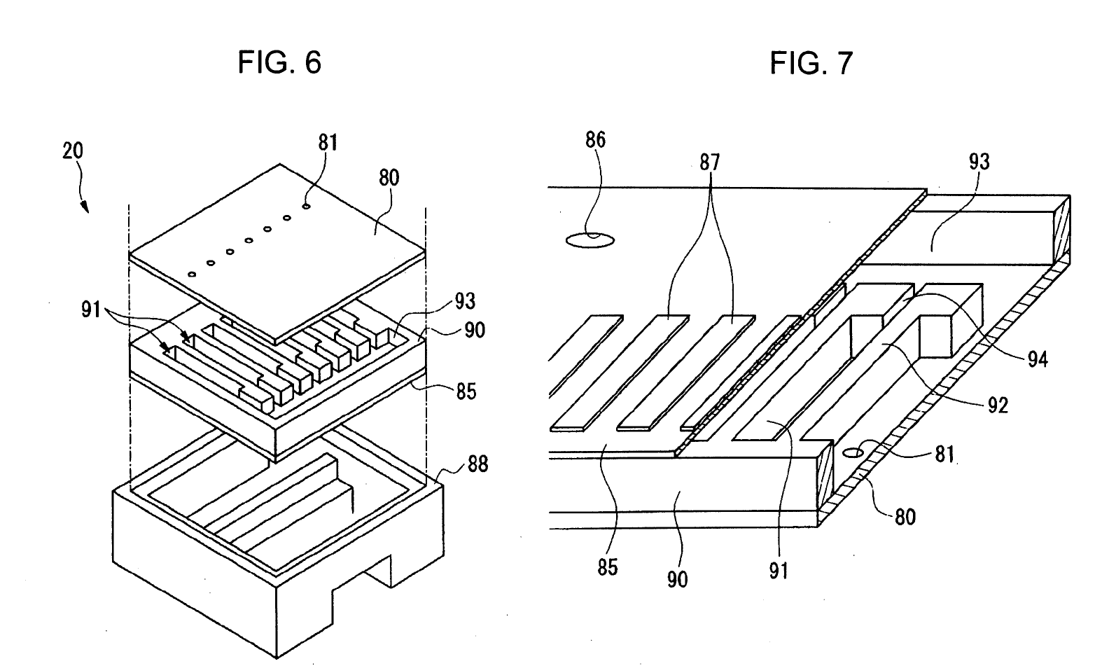

A droplet-discharging device used in the method according to the invention will be described. FIG. 5 is a schematic perspective view showing a droplet-discharging device used in producing an organic electroluminescent device according to the invention. FIGS. 6 and 7 each show a droplet-discharging head in the droplet-discharging device. In FIG. 5, a droplet-discharging device IJ is a film-forming device capable of disposing a droplet (ink drop) onto the surface of the substrate P. The droplet-discharging device IJ includes a base 12; a stage ST for supporting the substrate P, the stage ST being disposed on a base 12; a first transportation unit 14 movably supporting the stage ST, the electroluminescent layer 14 being disposed between the base 12 and the stage ST; a droplet-discharging head 20 capable of quantitatively discharging (dropping) a droplet containing a predetermined material onto the substrate P supported with the stage ST; and a second transportation unit 16 movably supporting the droplet-discharging head 20. A controlling unit CONT controls the operation of the droplet-discharging device IJ including the droplet-discharging operation of the droplet-discharging head 20 and the transportation operations of the first and second first transportation units 14.

The first transportation unit 14 is disposed on the base 12 and positioned along the y-axis. The second transportation unit 16 is supported with supporters 16A disposed at a rear portion 12A and is disposed above the first transportation unit 14. The x-axis direction of the second transportation unit 16 is orthogonal to the y-axis direction of the first transportation unit 14. The x-axis direction is defined as the lateral direction of the base 12. The y-axis direction is defined as the direction perpendicular to the x-axis. Both the x-axis and the y-axis are horizontal. The z-axis is defined as the direction perpendicular to both the x-axis and the y-axis.

The first transportation unit 14 includes, for example, a linear motor, two guide rails 40 and 40, and a slider 42 movable along the guide rails 40 and 40. The slider 42 of the first transportation unit 14 that includes the linear motor can be positioned by being moved in the y-axis direction along the guide rails 40 and 40. The slider 42 is provided with a motor 44 for rotation (θZ) around the z-axis. The rotor of the motor 44 is fixed to the stage ST. Thus, by applying power to the motor 44, the rotor and the stage ST are rotated along the θZ direction; thus, the stage ST can be indexed. That is, the first transportation unit 14 can move the stage ST in the y-axis direction and the θZ direction.

The stage ST holds the substrate P and positions the substrate P at a predetermined position. The stage ST includes a sucking and holding unit 50 for holding the substrate P on the stage ST by sucking through a sucking hole 46A provided in the stage ST.

The second transportation unit 16 includes a linear motor, the supporters 16A, a bar 16B fixed on the supporters 16A, guide rails 62A on the bar 16B, and a slider 60 movably supported along the guide rails 62A in the x-axis direction. The slider 60 can be positioned by being moved in the x-axis direction along the guide rails 62A. The droplet-discharging head 20 is mounted on the slider 60.

The droplet-discharging head 20 includes motors 62, 64, 66, and 68 as positioning devices by rotation. The motor 62 can position the droplet-discharging head 20 by vertically moving the droplet-discharging head 20 along the z-axis to position it. The z-axis is defined as the direction (vertical direction) orthogonal to both the x-axis and the y-axis. The motor 64 can position the droplet-discharging head 20 along the P direction by rotating around the y-axis. The motor 66 can position the droplet-discharging head 20 along the y direction by rotating around the x-axis. The motor 68 can position the droplet-discharging head 20 along the a direction by rotating around the z-axis. That is, the second transportation unit 16 movably supports the droplet-discharging head 20 in the x- and z-axis directions. Furthermore, the second transportation unit 16 movably supports the droplet-discharging head 20 in the θX, θY, and θZ directions.

In this way, the droplet-discharging head 20, shown in FIG. 5, can be linearly moved on the slider 60 in the z-axis direction to be positioned. In addition, the droplet-discharging head 20 can be rotated along the α, β, and γ directions to be positioned. The position and orientation of a discharging face 20P of the droplet-discharging head 20 with respect to the substrate P on the stage ST can be precisely controlled. A plurality of nozzles are disposed at the discharging face 20P of the droplet-discharging head 20.

FIG. 6 is an exploded perspective view of the droplet-discharging head 20. The droplet-discharging head 20 includes a nozzle plate 80 having a plurality of nozzles 81, a pressure chamber substrate 90 having a diaphragm 85, and a case 88 in which the nozzle plate 80 and the diaphragm 85 are embedded. As shown in FIG. 7, the droplet-discharging head 20 mainly has a structure in which the pressure chamber substrate 90 is provided between the nozzle plate 80 and the diaphragm 85. The nozzles 81 in the nozzle plate 80 correspond to respective cavities 91 into which the pressure chamber substrate 90 is partitioned. By etching the pressure chamber substrate 90 composed of, for example, a silicon single crystal, a plurality of cavities 91 are formed so as to function as pressure chambers. The cavities 91 are separated with side walls 92. Each of the cavities 91 is connected to a reservoir 93 through a feeding aperture 94, the reservoir 93 serving as a common passage. The diaphragm 85 is composed of, for example, a thermally grown oxide film.

A tank port 86 is provided in the diaphragm 85. A liquid material can be fed through a pipe (passage) 31 from a tank 30, shown in FIG. 5. Piezoelectric elements 87 are disposed on the diaphragm 85 at positions corresponding to the respective cavities 91. Each of the piezoelectric elements 87 includes a piezoelectric ceramic crystal, such as PZT, disposed between an upper electrode and a lower electrode (not shown). The piezoelectric elements 87 can change the volume thereof according to a discharging signal from the controlling unit CONT.

To discharge a droplet from the droplet-discharging head 20, the controlling unit CONT supplies the droplet-discharging head 20 with a discharging signal for discharging a droplet. The liquid material is in the cavities 91 of the droplet-discharging head 20. Each of the piezoelectric elements 87 of the droplet-discharging head 20 generates a change in volume by applying a voltage between the upper electrode and the lower electrode. This change in volume causes deformation of the diaphragm 85, thus changing the volume of the corresponding cavity 91. As a result, a droplet is discharged through the corresponding nozzle 81 at the cavity 91. The amount of liquid material discharged is fed from the tank 30 to the cavity 91 where the droplet is discharged.

The droplet-discharging head 20 provided in the droplet-discharging device IJ according to this embodiment discharges a droplet based on a change in the volume of the piezoelectric element, but may discharge a droplet based on expansion of a liquid material heated by a heater.

As shown in FIG. 5, the liquid material to be provided on the substrate P is prepared with a liquid-material-adjusting device S. The liquid-material-adjusting device S includes the tank 30 containing the liquid material, a temperature-adjusting device 32 for controlling the temperature of the liquid material in the tank 30, the temperature-adjusting device 32 being attached to the tank 30, and a stirrer 33 for stirring the liquid material in the tank 30. The temperature-adjusting device 32 is a heater and controls the temperature of the liquid material in the tank 30 to a predetermined temperature. The temperature-adjusting device 32 is controlled with the controlling unit CONT. The liquid material in the tank 30 has a predetermined viscosity by controlling the temperature of the liquid material with the temperature-adjusting device 32.

The tank 30 is connected to the droplet-discharging head 20 through the pipe (passage) 31. The liquid material that is discharged from the droplet-discharging head 20 is fed from the tank 30 through the pipe 31. The temperature of the liquid material in the pipe 31 is controlled by a pipe-temperature-adjusting device (not shown), thereby adjusting the viscosity of the liquid material. Furthermore, the temperature of the droplet to be discharged from the droplet-discharging head 20 is controlled by a temperature-controlling device (not shown) on the droplet-discharging head 20, thereby adjusting the viscosity of the liquid material to a target viscosity value.

<Manufacturing Procedure of Organic Electroluminescent Device>

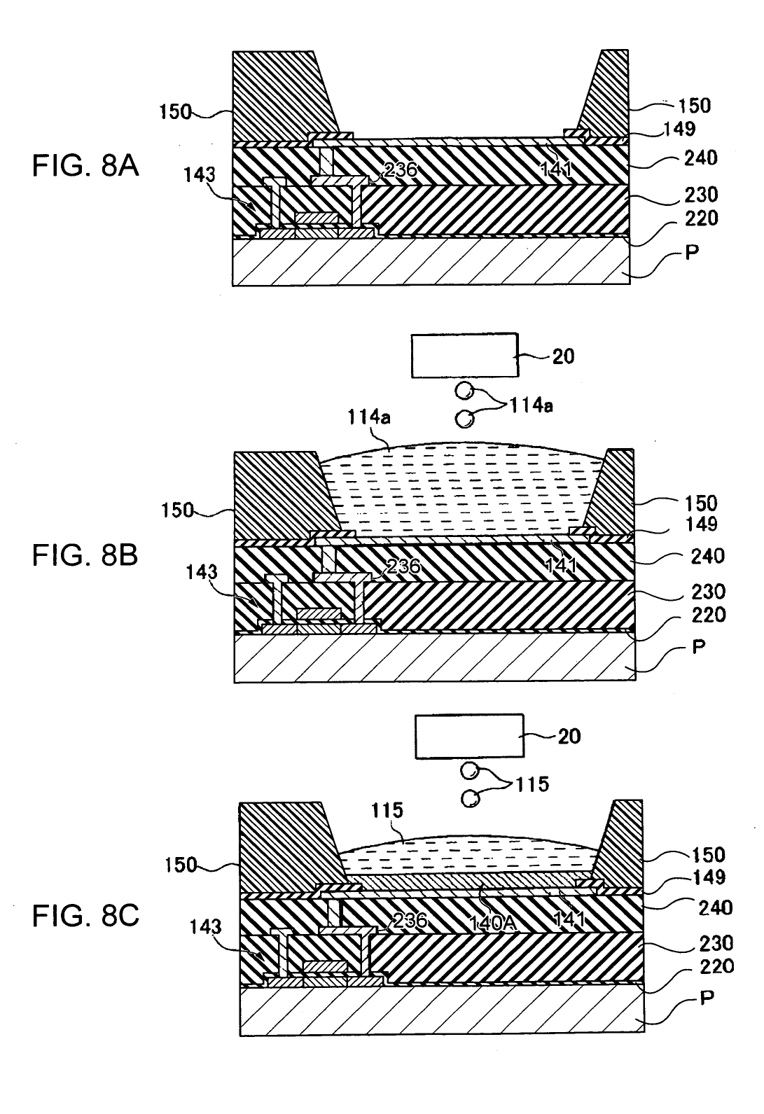

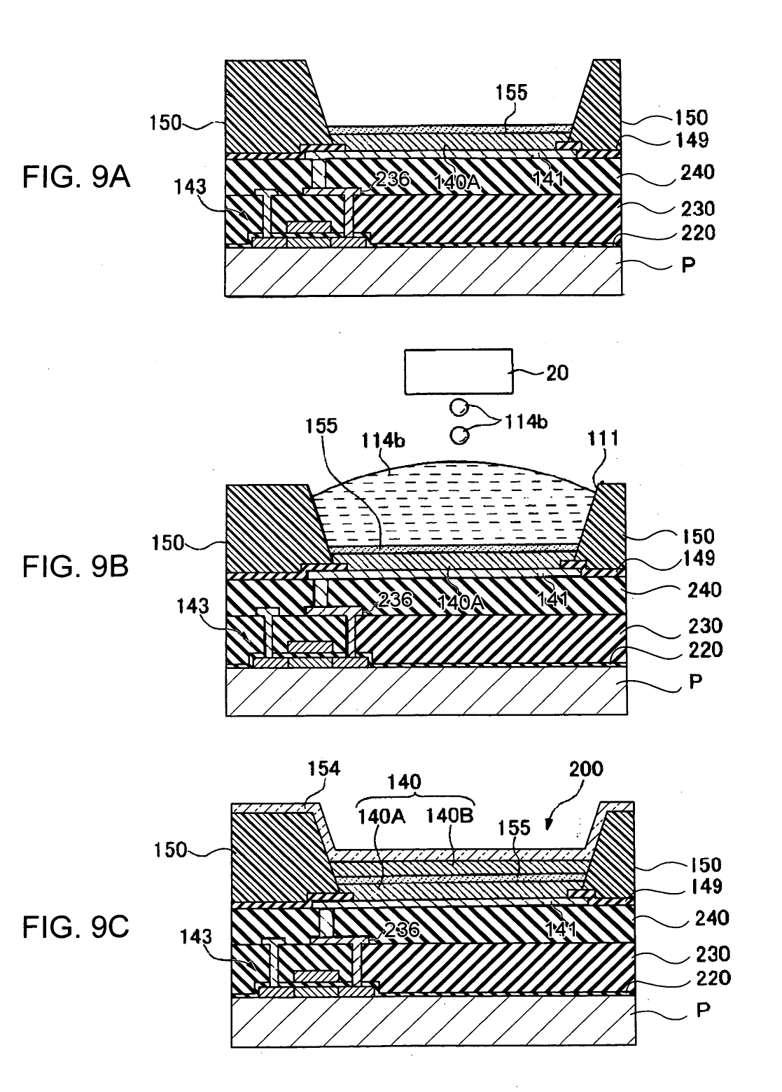

The manufacturing procedure of an organic electroluminescent device according to the invention using the droplet-discharging device IJ will be described below with reference to FIGS. 8A to 8C and 9A to 9C.

As shown in FIG. 8A, the driving TFT 143 is formed on the substrate P such as a glass substrate. The pixel electrode 141 connected to the driving TFT 143 is formed. Then, the inorganic banks 149 and the (organic) banks 150 are formed along the periphery of the pixel electrode 141.

The banks 150 function as partitions. The banks 150 can be formed by lithography, printing, or any other process. For example, when employing the lithography, an organic photo-sensitive material is applied on the substrate P according to the height of a predetermined bank by a predetermined process such as spin coating, spray coating, roll coating, die coating, or dipping. A resist is applied on the resulting layer. A mask having the shape of the bank (pixel arrangement) is provided on the resist layer. The resist layer is formed in the bank shape by exposure and development. Then, the bank material other than the bank material under the mask is removed by etching. Alternatively, each of the banks (convex portions) may be formed of at least two layers including a lower layer composed of a lyophilic inorganic or organic material and an upper layer composed of a lyophobic organic material.

An organic material for the bank may be a material originally lyophobic to liquid materials (a material for the hole-transporting layer, a material for the luminescent layer, and a material for the intermediate layer) and also may be an organic insulation material that can be imparted liquid repellency by plasma treatment, has good adhesion to a bottom layer, and is easily patterned by photolithography. An organic material such as an acrylic resin, a polyimide resin, an olefin resin, or a melamine resin can be used.

To remove the residual resist (organic material) between the banks, the substrate P is subjected to removal treatment.

For example, ultraviolet (UV) irradiation treatment for removing residues by irradiation of ultraviolet rays or oxygen-plasma treatment for removing residues with oxygen as a treatment gas in an air atmosphere may be employed as the residual treatment. In this embodiment, the oxygen-plasma treatment is performed. Thus, the lyophilic property of the surface of the pixel electrode 141 can be improved.

Subsequently, the banks 150 are subjected to lyophobic treatment to impart a lyophobic property to the surfaces of the banks 150. For example, plasma treatment with tetrafluoromethane as a treatment gas in an air atmosphere (CF₄ plasma treatment) can be employed as the lyophobic treatment.

Other fluorocarbon gases, such as SF₆ and CHF₃, may be used as the treatment gas in addition to tetrafluoromethane.

A fluorine-containing group is introduced into a resin constituting the banks 150 by such a lyophobic treatment, thus imparting a high lyophobic property. The oxygen-plasma treatment (lyophilic treatment) may be performed after formation of the banks 150. However, the oxygen-plasma treatment is preferably performed before formation of the banks 150 because the acrylic resin and the polyimide resin are readily fluorinated after the oxygen-plasma treatment rather than before the oxygen-plasma treatment.

Even when the entire surface of the base is subjected to such a lyophobic treatment, the surfaces of the pixel electrode 141 and the inorganic banks 149 composed of an ITO film or a metal film are difficult to have the lyophobic property compared with the surface of the banks 150 composed of an organic material. As a result, only the surfaces of the banks 150 are selectively imparted the lyophobic property. Therefore, a plurality of regions having different affinities to a liquid material are formed in the region surrounded by the banks 150.

The driving TFT 143, the pixel electrode 141, and the inorganic bank 149 may be formed by known processes. In this specification, descriptions of these manufacturing procedures are omitted.

As shown in FIG. 8B, the substrate P is placed so that the upper surface of the substrate P (aperture of the banks 150) faces upward. A liquid material 114a containing a material for the hole-transporting layer is selectively applied to predetermined positions surrounded by the bank 150 with the droplet-discharging head 20. The liquid material 114a for the hole-transporting layer is prepared with the liquid-material-adjusting device S shown in FIG. 5. The liquid material 114a contains a material for the hole-transporting layer and a solvent. For example, a dispersion containing PEDOT/PSS is used as the liquid material 114a. In this embodiment, the hole-transporting layer is formed by the droplet-discharging process. The hole-transporting layer may be formed by slit coating (or curtain coating) or die coating, using a portion having a non-affinity (lyophobic) and a portion having an affinity (lyophilic).

When the liquid material 114a containing a material for the hole-transporting layer is discharged onto the substrate P from the droplet-discharging head 20, the liquid material 114a tends to spread because of its high fluidity. However, since the liquid material 114a discharged on the substrate P is surrounded by the banks 150, the liquid material 114a cannot spread over the banks 150.

Subsequently, the solvent in the liquid material 114a is evaporated by heating or light irradiation to produce the solid hole-transporting sublayer 140A on the pixel electrode 141. Alternatively, the liquid material 114a applied may be baked at a predetermined temperature for a predetermined period (for example, 200° C. for 10 minutes) in an air atmosphere or a nitrogen gas atmosphere. Furthermore, the solvent may be evaporated at a reduced pressure (under vacuum conditions).

Then, the intermediate layer 155 is formed on the hole-transporting sublayer 140A. In this embodiment, the procedures for forming the intermediate layer 155 by chemical vapor deposition, dipping, spin coating, and droplet discharging, will be described below.

(Chemical Vapor Deposition)

The substrate P including the hole-transporting sublayer 140A formed according to the-above manufacturing procedure is placed in a 300 ml Teflon® container. Then, 20 μL of phenyltriethoxysilane, which is a material constituting an organic thin film functioning as the intermediate layer, is introduced into a 20 mL sample bottle. The uncovered sample bottle is placed in the Teflon® container with the substrate. The Teflon® container is tightly sealed and placed in an electric oven. The temperature in the oven is raised to 120° C. and maintained for 1 hour. Then, the container is removed from the electric oven. In this way, as shown in FIG. 9A, the intermediate layer 155 is formed on the hole-transporting sublayer 140A.

The film thickness was measured by an ellipsometer. Formation of a phenyltriethoxysilane film was identified by measurement with an atomic force microscope (AFM) and X-ray photoelectron spectroscopy (XPS). Table 1 shows contact angles of water and a material for the luminescent layer on the phenyltriethoxysilane film formed by depositing the material for 1 hour and on the hole-transporting layer.

TABLE 1

Contact angle-
measured medium

| | | Material for |
|---|---|---|
| | | luminescent |
| | | layer |
| Measured surface | Water | (polyfluorene) |
| Hole-transporting layer | 5°≦ | 25° |
| (PEDOT/PSS) | | |
| Phenyltriethoxysilane film | 55° | 5°≦ |

The contact angle of water on the phenyltriethoxysilane film was increased and the contact angle of the material for the luminescent layer on the phenyltriethoxysilane film was reduced; hence, formation of an affinity film composed of lipophilic film was confirmed. The surface energy of the phenyltriethoxysilane film was calculated from the contact angles of water, methylene iodide, and hexadecane. As a result, the surface energy was found to be 35 mN/m. The surface energy of a free silanol group Si—OH, which does not form a chemically adhering film, was 80 mN/m.

When the intermediate layer 155 contains a material, for example, phenyltriethoxysilane, the hydrolyzable groups (X¹ or X²) are predominantly adsorbed on the surface of the hole-transporting sublayer 140A. Thus, the phenyl groups, each functioning as a nonpolar group, are arranged at the surface of the intermediate layer 155. As a result, the intermediate layer 155 is a monomolecular film or a laminate thereof. The intermediate layer 155 is preferably formed so that the intermediate layer 155 has a thickness of about 1 to 10 molecular layers. This low thickness provides satisfactory effect without deterioration of charge mobility between the hole-transporting sublayer 140A and the luminescent sublayer 140B.

(Dipping)

To a glass staining vat (44×98×41 mm), 100 ml of a 1 wt % benzyltrimethoxysilane toluene solution is fed. A substrate is immersed in the solution at 25° C. for 1 hour. The substrate is taken out and washed twice with dehydrated toluene to remove an excess organic thin film, thus resulting in the intermediate layer 155 on the hole-transporting sublayer 140A. As in the case of the chemical vapor deposition, the intermediate layer 155 can also be produced on the hole-transporting sublayer 140A by dipping.

(Droplet-Discharging Process)

As shown in FIG. 8C, the substrate P is placed so that the upper surface of the substrate P faces upward. A liquid material 115 containing a material for the intermediate layer and a solvent is selectively applied onto the hole-transporting sublayer 140A surrounded by the banks 150 from the droplet-discharging head 20. Since the banks 150 having repellency to the liquid material 115, even when the liquid material 115 is discharged onto the banks 150, the liquid material 115 is repelled by the bank 150 to slip onto the hole-transporting sublayer 140A. In this way, formation of the intermediate layer 155 on the surface of the bank 150 can be prevented. Subsequently, the solvent is evaporated to produce the intermediate layer 155, as shown in FIG. 9A.

As shown in FIG. 9B, after the formation of the intermediate layer 155 on the hole-transporting sublayer 140A, a liquid material 114b containing a material for the luminescent layer and a solvent is applied to the intermediate layer 155 surrounded by the bank 150 by discharging the liquid material 114b from the droplet-discharging head 20. In this embodiment, suitable examples of the solvent of the liquid material 114b include nonpolar solvents such as cyclohexylbenzene, dihydrobenzofuran, trimethylbenzene, and tetramethylbenzene. This is because these solvents have an excellent affinity to the nonpolar group in phenyltriethoxysilane.

when applying the liquid material 114b, the liquid material 114b can wet and spread on the surface of the intermediate layer 155 because of the effect of the intermediate layer 155. Then, the portion surrounded by the banks 150 is uniformly filled with the liquid material 114b.

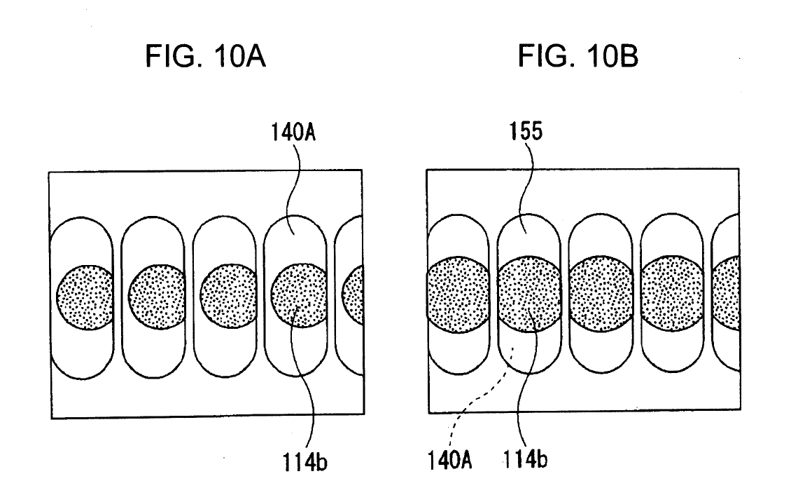

As shown in FIG. 10A, when the liquid material 114b containing a material for the luminescent layer was discharged onto the hole-transporting sublayer 140A without the intermediate layer 155, the droplets unsatisfactorily wet and spread because of its low affinity. On the other hand, as shown in FIG. 10B, when the liquid material 114b containing a material for the luminescent layer was discharged onto the intermediate layer 155 on the hole-transporting sublayer 140A, since the affinity was improved, the droplets satisfactorily wet and spread to produce the luminescent layers each having a uniform thickness.

When a color organic electroluminescent display in which organic electroluminescent elements for a plurality of colors are arranged on a substrate is manufactured, the liquid materials 114b, that is, a liquid material containing a material for the luminescent layer emitting red light (for example, cyano-substituted polyphenylene vinylene), a liquid material containing a material for the luminescent layer emitting green light (for example, polyphenylene vinylene), and a liquid material containing a material for the luminescent layer emitting blue light (for example, polyphenylene vinylene and polyalkylphenylene) (these compounds, available in liquid form, manufactured by Cambridge Display Technology Ltd.) are applied to the respective portions (pixels 71) surrounded by the banks 150 by discharging, thus producing the luminescent layers. The pixels 71 corresponding to these colors have a regular arrangement.

After applying each of the liquid materials 114b containing the corresponding material for each luminescent layer, the solvents in the liquid materials 114b. As shown in FIG. 9C, each of the solid luminescent layers 140B is formed on the corresponding hole-transporting sublayer 140A. The liquid materials 114b are uniformly applied by virtue of the respective intermediate layers 155. Therefore, the resulting luminescent layers 140B each have a uniform thickness and quality.

In this way, the organic functional layer 140 including the hole-transporting sublayer 140A and the luminescent sublayer 140B is produced. The solvents in the liquid materials 114b containing materials for the luminescent layers are evaporated by, for example, heating or under a reduced pressure, if necessary. The materials for the luminescent layers usually have excellent drying characteristics and rapid drying properties; hence, such an evaporation treatment is not required. Therefore, during successively applying the materials for the luminescent layers, the luminescent layers 140B can be formed in that order.

As shown in FIG. 9C, the common electrode 154 composed of a transparent conductive material is formed on the entire surface of or in the form of a striped pattern on the transparent substrate P. In this way, the organic electroluminescent element 200 can be produced. In this embodiment, the organic electroluminescent element 200 includes the pixel electrode 141, the hole-transporting sublayer 140A, the luminescent sublayer 140B, and the common electrode 154.

As described above, in this embodiment, since the affinity between the hole-transporting sublayer 140A and the luminescent sublayer 140B is improved using the intermediate layer 155, even when the luminescent sublayer 140B is formed with a different solvent in view of compatibility, the liquid material 114b containing a material for the luminescent layer can wet and spread; hence, the luminescent sublayer 140B can be uniformly formed on the hole-transporting sublayer 140A.

Furthermore, in this embodiment, the bank 150 has repellency to a material for the hole-transporting layer, a material for the luminescent layer, and a material for the intermediate layer. Thus, formation of the intermediate layer on the bank 150 can be prevented.

(Electronic Apparatus)

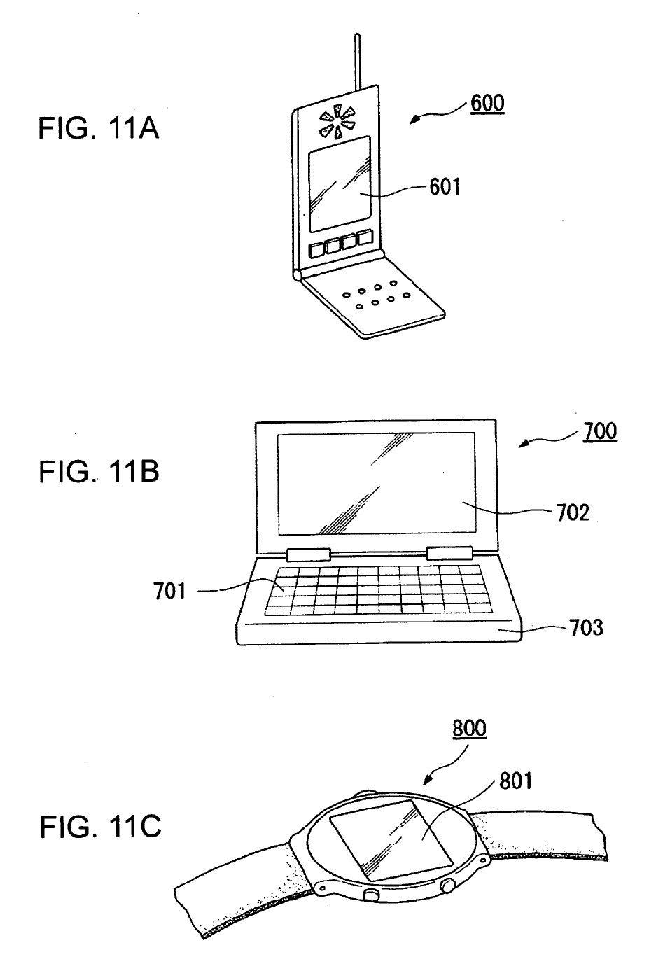

FIGS. 11A to 11C each are perspective view showing an example of an electronic apparatus according to the invention.

FIG. 11A is a perspective view showing an example of a cellular phone. Reference numeral 600 represents a main body of the cellular phone, and reference numeral 601 represents a display to which the organic electroluminescent display 70 is applied. In FIG. 11B is a perspective view showing an example of a portable information processor such as a word processor or a personal computer. Reference numeral 700 represents an information processor, and reference numeral 701 represents an input portion such as keyboard, reference numeral 702 represents a display to which the organic electroluminescent display 70 is applied, and reference numeral 703 represents a main body of the information processor. FIG. 11C is a perspective view showing an example of electronic apparatus of a wristwatch type. Reference numeral 800 represents a main body of the wristwatch and reference numeral 801 represents a display to which the organic electroluminescent display 70 is applied. The electronic apparatuses shown in FIGS. 11A to 11C each have the organic electroluminescent display 70 according to the embodiment and can thus display with high image quality and uniform brightness.

The scope of the invention is not limited to the embodiment. The invention is intended to cover various modifications and equivalent arrangements included within the spirit and scope of the invention. Specific materials and the layer structures are merely examples and can be appropriately modified.

For example, in the above-described embodiment, the hole-transporting sublayer 140A is adjacent to the luminescent sublayer 140B with the intermediate layer 155 therebetween. However, the invention is not limited to the structure. A hole-injecting layer may be provided instead of the hole-transporting sublayer 140A.

Furthermore, the organic functional layer 140 is composed of the hole-transporting sublayer 140A and the luminescent sublayer 140B. However, the invention is not limited to the structure. The organic functional layer 140 may have a multilayer structure having at least three layers. For example, a hole-injecting layer may be provided between the pixel electrode 141 and the hole-transporting sublayer 140A. For example, an electron-transporting layer, an electron-injecting layer may be provided between the luminescent sublayer 140B and the common electrode 154, if necessary. Providing these layers can suppress an increase in driving voltage, thus achieving a long driving life (half-life period).

Furthermore, one organic electroluminescent element 200 need not to have only one intermediate layer 155. In the above-described embodiments, the intermediate layer 155 is provided between the hole-transporting sublayer 140A and the luminescent sublayer 140B. In addition, a plurality of the intermediate layers 155 may be provided at desired positions between the pixel electrode 141 and the common electrode 154.

Furthermore, in the above-described embodiment, the hole-transporting sublayer 140A and the luminescent sublayer 140B are provided in that order, from the substrate P. The luminescent sublayer 140B and the hole-transporting sublayer 140A may be provided in that order, from the substrate P. In this case, the intermediate layer 155 functioning as an affinity film should be provided on the luminescent sublayer 140B. In addition, the hole-transporting sublayer 140A should be provided on the intermediate layer 155.

1. An organic electroluminescent device comprising:
a hole-injecting or hole-transporting layer;
a luminescent layer; and
an affinity film for improving an affinity between the hole-injecting or hole-transporting layer and the luminescent layer, the hole-injecting or hole-transporting layer and the luminescent layer being formed by a droplet-discharging process, wherein the affinity film is disposed between the hole-injecting or hole-transporting layer and the luminescent layer.

2. The organic electroluminescent device according to claim 1, wherein the affinity film comprises a silane compound or a surfactant.

3. The organic electroluminescent device according to claim 1, further comprising:
a partition for partitioning the hole-injecting or hole-transporting layer and the luminescent layer, the partition having liquid repellency against a material constituting the affinity film.

4. The organic electroluminescent device according to claim 1, wherein the affinity film is formed by chemical vapor deposition, dipping, spin coating, or droplet discharging.

5. An electronic apparatus comprising the organic electroluminescent device according to claim 1.

6. A method for producing an organic electroluminescent device, comprising:
forming a hole-injecting or hole-transporting layer by a droplet-discharging process;
forming a luminescent layer by the droplet-discharging process; and
forming an affinity film on either the luminescent layer or the hole-injecting or hole-transporting layer to improve an affinity between the hole-injecting or hole- transporting layer and the luminescent layer.

7. The method for producing the organic electroluminescent device according to claim 6, wherein the affinity film comprises a silane compound or a surfactant.

8. The method for producing the organic electroluminescent device according to claim 6, further comprising:
forming a partition for partitioning the hole-injecting or hole-transporting layer and the luminescent layer, the partition having liquid repellency against a material constituting the affinity film.

9. The method for producing the organic electroluminescent device according to claim 6, wherein the affinity film is formed by chemical vapor deposition, dipping, spin coating, or droplet discharging.
